(19) United States
(12) Patent Application Publication
(10) Pub. No.: US 2004/0189410 A1
(43) Pub. Date: Sep. 30, 2004

(54) Oscillator operating close to transistor's fmax

(76) Inventor: Luiz M. Franca-Neto, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/400,756

(22) Filed: Mar. 26, 2003

(51) Int. Cl. H03B 11/10

(52) U.S. Cl. 331/107 SL

(57) ABSTRACT

An oscillator operating close to transistor's fₘₐₓ based on one or several repetitions of an amplifier design using simultaneous input and output matching, and thus designed, the oscillator may operate at the optimum pumping regime a given technology can provide. Phase condition for oscillations is provided by the strategic addition of lossless (purely real characteristic impedance) delays.

In general, wireless devices may communicate with one another by translating a carrier frequency of a modulated signal. On the transmitter side, information signals may be heterodyned to higher frequencies to operate with more bandwidth. On the receiver side, information signals are translated in frequency down to base band frequencies for processing. Oscillators are a key component in the receiver for image rejection, synchronization and detection of signals.

There is a continuing need for better ways to provide frequency translation while providing flexibility for operating a high data-rate wireless transceiver.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates features of the present invention that may be incorporated into a wireless communications device;

FIG. 2 illustrates cross-coupled N-channel CMOS transistors and the associated general network of an oscillator in accordance with the present invention;

FIG. 3 illustrates how the oscillator shown in FIG. 2 may be unraveled into a generalized cell network having identical segment instantiation;

FIG. 4 is a Smith chart that illustrates impedance conversion for one embodiment of an oscillator;

FIG. 5 illustrates a representative microstrip network and amplifiers for the oscillator corresponding to the Smith chart shown in FIG. 4;

FIG. 6 is a Smith chart that illustrates impedance conversion for another embodiment of an oscillator;

FIG. 7 illustrates a representative microstrip network and amplifiers for the oscillator corresponding to the Smith chart shown in FIG. 6;

FIG. 8 is a Smith chart that illustrates impedance conversion for yet another embodiment of an oscillator; and

FIG. 9 illustrates a representative microstrip network and amplifiers for the oscillator corresponding to the Smith chart shown in FIG. 8.

It will be appreciated that for simplicity and clarity of illustration, elements illustrated in the figures have not necessarily been drawn to scale. For example, the dimensions of some of the elements may be exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

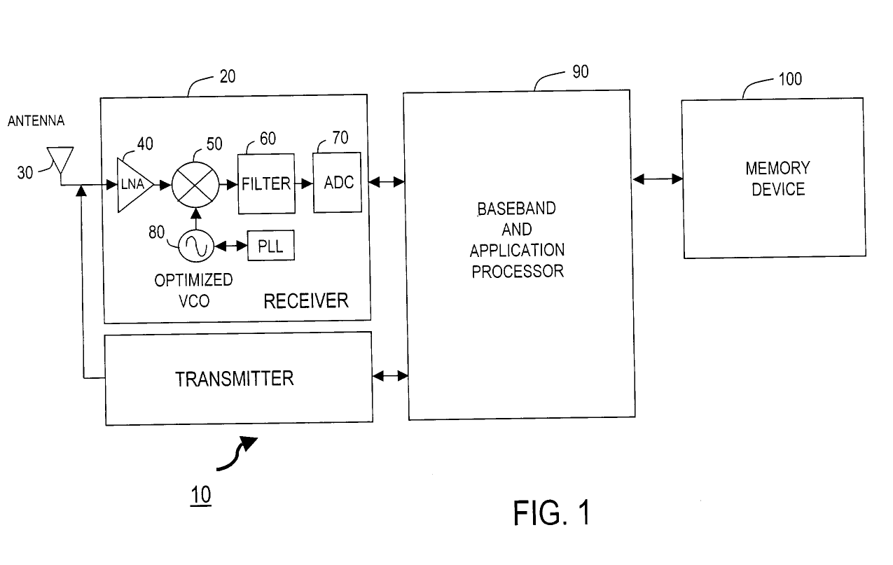

FIG. 1 illustrates features of the present invention for an oscillator operating close to transistor's fₘₐₓ that may be incorporated in a wireless communications device 10. The transceiver for wireless communications device 10 either receives or transmits a modulated signal from an antenna 30. A Low Noise Amplifier (LNA) 40 amplifies the received signal and a mixer circuit 50 translates the carrier frequency of the modulated signal, up-converting the frequency of the modulated signal in the transmitter and down-converting the frequency of the modulated signal in the receiver. The down-converted signal may be filtered through a filter 60 and converted to a digital representation by an Analog-To-Digital Converter (ADC) 70. A baseband and application processor 90 is connected to the transceiver to provide, in general, the digital processing of the received data within communications device 10.

Optimized oscillator 80 and associated analog circuitry may be embedded with processor 90 as a mixed-mode integrated circuit, or alternatively, optimized oscillator 80 may be incorporated into the transceiver as a stand-alone Radio Frequency (RF) integrated circuit. In one embodiment, oscillator 80 generates signals for mixer circuit 50 used to down convert the received modulated signal. Accordingly, embodiments of the present invention may be used in a variety of applications, with the claimed subject matter incorporated into microcontrollers, general-purpose microprocessors, Digital Signal Processors (DSPs), Reduced Instruction-Set Computing (RISC), Complex Instruction-Set Computing (CISC), among other electronic components. In particular, the present invention may be used in smart phones, communicators and Personal Digital Assistants (PDAs), base band and application processors, medical or biotech equipment, automotive safety and protective equipment, and automotive infotainment products. However, it should be understood that the scope of the present invention is not limited to these examples.

Further, the principles of the present invention may be practiced in wireless devices that are connected in a Code Division Multiple Access (CDMA) cellular network and distributed within an area for providing cell coverage for wireless communication. Additionally, the principles of the present invention may be practiced in Wireless Local Area Network (WLAN), 802.11, Orthogonal Frequency Division Multiplexing (OFDM), Ultra Wide Band (UWB), and Global System for Mobile Communications (GSM), among others.

A memory device 100 may be connected to processor 90 to store data and/or instructions. In some embodiments, memory device 100 may be volatile memories such as, for example, a Static Random Access Memory (SRAM), a Dynamic Random Access Memory (DRAM) or a Synchronous Dynamic Random Access Memory (SDRAM), although the scope of the claimed subject matter is not limited in this respect. In alternate embodiments, the memory devices may be nonvolatile memories such as, for example, an Electrically Programmable Read-Only Memory (EPROM), an Electrically Erasable and Programmable Read Only Memory (EEPROM), a flash memory (NAND or NOR type, including multiple bits per cell), a Ferroelectric Random Access Memory (FRAM), a Polymer Ferroelectric Random Access Memory (PFRAM), a Magnetic Random Access Memory (MRAM), an Ovonics Unified Memory (OUM), a disk memory such as, for example, an electromechanical hard disk, an optical disk, a magnetic disk, or any other device capable of storing instructions and/or data. However, it should be understood that the scope of the present invention is not limited to these examples.

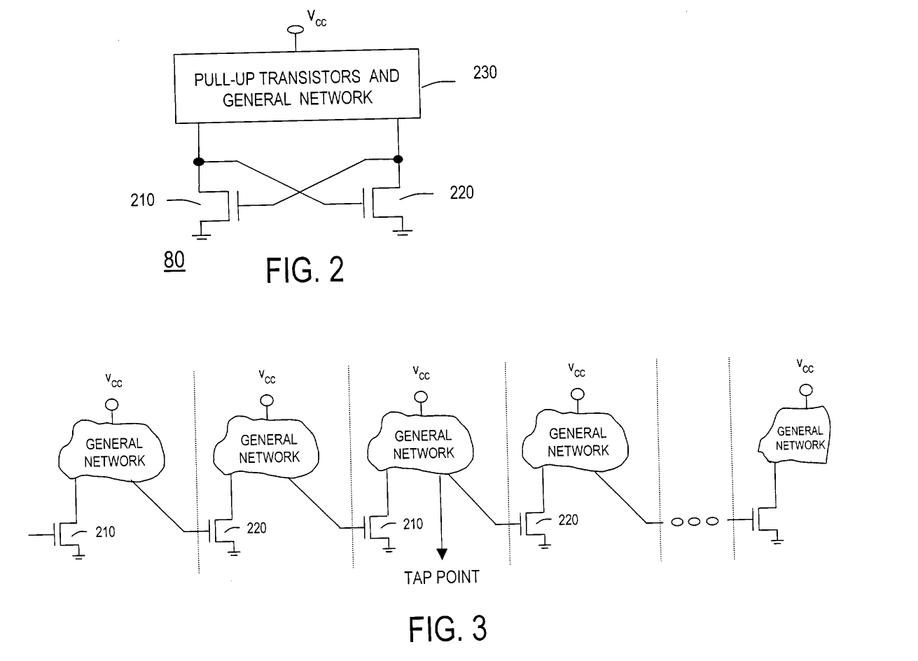

FIG. 2 illustrates cross-coupled N-channel Complementary Metal Oxide Semiconductor (CMOS) transistors 210 and 220 and associated general network 230 of optimized oscillator 80.

FIG. 3 illustrates how oscillator 80 (see FIG. 2) may be unraveled into a generalized cell network having identical segment instantiation. Comparing FIGS. 2 and 3, it should be noted that oscillator 80 may be unraveled into an infinite number of amplifiers denoted by a repeating sequence of transistors 210 and 220. Importantly, each of the amplifiers may be designed to exploit the maximum gain that a given transistor technology can provide. The phase condition for oscillation may be independently attended by closing the loop following an amplifier selected at a point in the sequence where the phase shift is 360 degrees or a multiple of 360 degrees. The phase shift is accrued from the first amplifier by a signal entering the sequence of amplifiers. Therefore, depending on the actual transistor technology used and the frequency of operation targeted, the oscillator loop may be closed with one or more transistors in the loop, where the total number of transistors may be either even or odd.

It should be pointed out that in targeting operating frequencies close to a transistor's fₘₐₓ, e.g., the transistor's maximum oscillating frequency, the amplifier may be designed to provide all the gain for which it is capable. Oscillators that are built with amplifiers using simultaneous input and output impedance matching are said to be operating at optimum pumping between its active and passive components. In other words, an oscillator built having amplifiers that operate at maximum power gain where the input and output impedance simultaneously match, may provide the highest frequency of operation for a given transistor technology. However, the simultaneous matching of input and output impedance may not always be possible over all operating frequencies, but it is possible at those frequencies where the transistor is unconditionally stable. It just so happen that as the frequency of operation gets close to fₘₐₓ, transistors naturally tend to be unconditionally stable.

The number of amplifiers required in an oscillator chain to attend to the requirement of 360 degrees of phase shift (or multiple of 360 degrees) may be set by adding delays that are strategically located along the lossless passive network. The lossless passive network converts the gate impedance at one amplifier into the matched output impedance of the previous amplifier. Since this passive network is lossless it provides not only matched output at the previous amplifier, it also provides simultaneously matched input to the following amplifier as desired for optimum pumping designs.

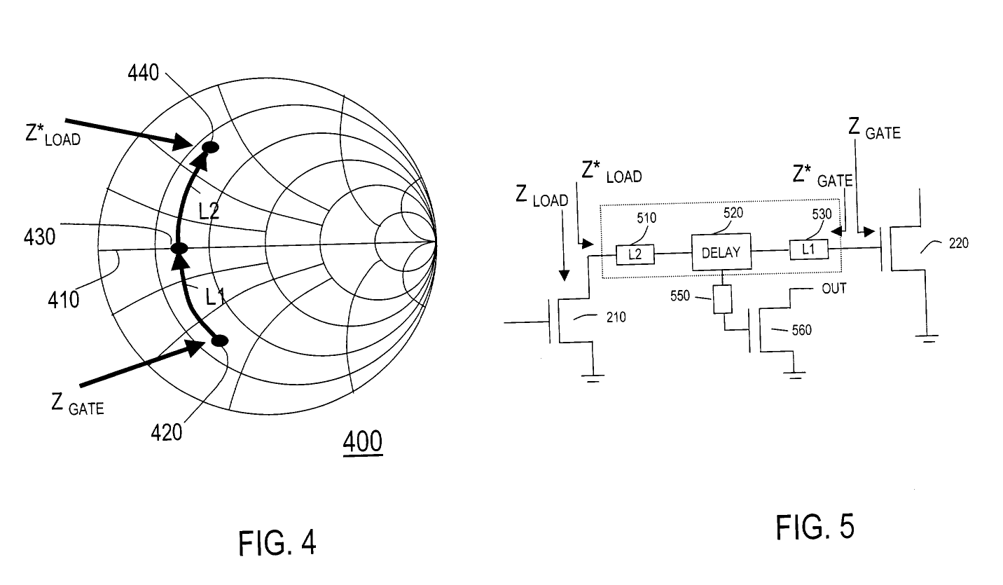

FIG. 4 depicts a Smith chart 400 and FIG. 5 illustrates amplifiers 210, 220 that may be incorporated into an oscillator design where the amplifiers have simultaneously matched input and output impedances. In this embodiment, a single transmission line segment converts the input impedance at the gate of an amplifier into the complex conjugate of the output impedance of the previous amplifier. The input impedance at the gate of an amplifier is labeled in the Smith chart as Z_{GATE} 420 and the output impedance of the previous amplifier is labeled as Z_{LOAD} 440. A single transmission line of combined length L1+L2 transforms the input impedance Z_{GATE} into the output impedance Z*_{LOAD}, i.e., the complex conjugate of Z_{LOAD}.

Observe that after adding the transmission line having a segment length of L1, Z_{GATE} is transformed into a real impedance. This allows for the strategic placement of a delay segment 520 provided by a transmission line segment having a specific real impedance. Delay segment 520 is placed between transmission line segment 510 and transmission line segment 530 and has a characteristic impedance defined by the point 430 on the real axis of Smith Chart 400 in FIG. 4 (the real impedance segment L1 transformed Z_{GATE} into). This additional delay segment 520 will not disturb the optimum pumping but the addition of the delay segment allows the oscillator loop to be closed with a different number of amplifier stages. Note that the delay segments complete the phase requirement for oscillations to be sustained in oscillator 80.

Thus, a network including at least transmission lines 510 and 530 having lengths L2 and L1 and separated by a delay segment 520 provide optimum pumping for oscillator 80. Since the delay lines are also the points of smallest impedance, they are also the points where oscillation signals may be tapped to provide an output with minimum disturbance to the amplifier core of the oscillator.

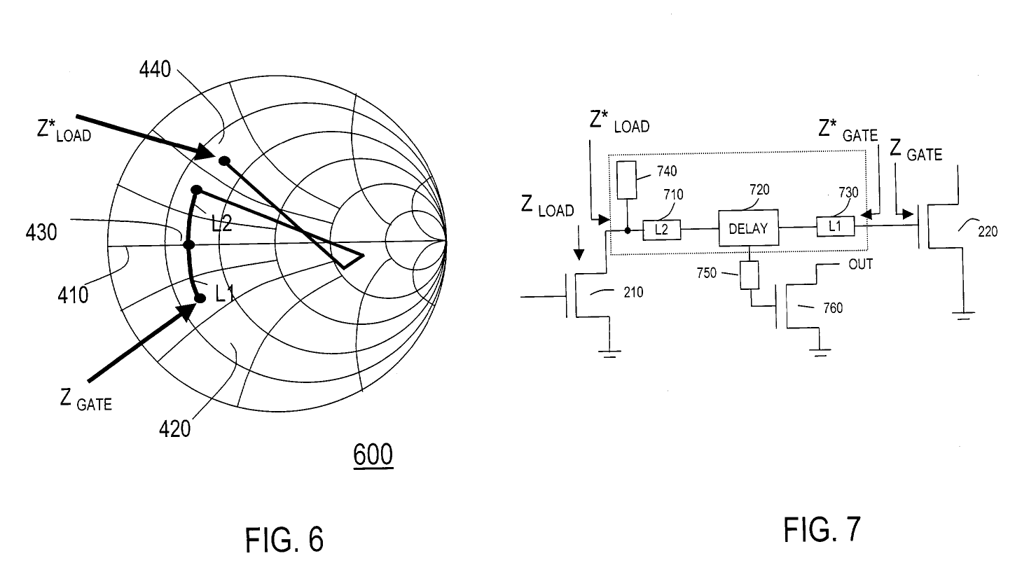

FIGS. 6 and 7 depict a Smith chart 600 and corresponding amplifiers 210 and 220 that along with a network may be used for oscillator 80. The network includes transmission lines 710 and 730 having lengths L2 and L1 and separated by a delay segment 720. In this embodiment and depending on the transistor used, the passive network may be more complex than a single piece of transmission line. Note the addition of transmission line 740 to the drain of transistor 210. However, it should be understood that simultaneous matching of input and output in the core amplifiers will lead to transmission line segments which cross the horizontal axis 410 of Smith chart 600, thus offering opportunities to add lossless delay lines. These points where the delay lines are added also offer convenient locations where tap points may be inserted. Transmission line 750 and transistor 760 provide a tap point inserted into delay 720 for providing the signal OUT.

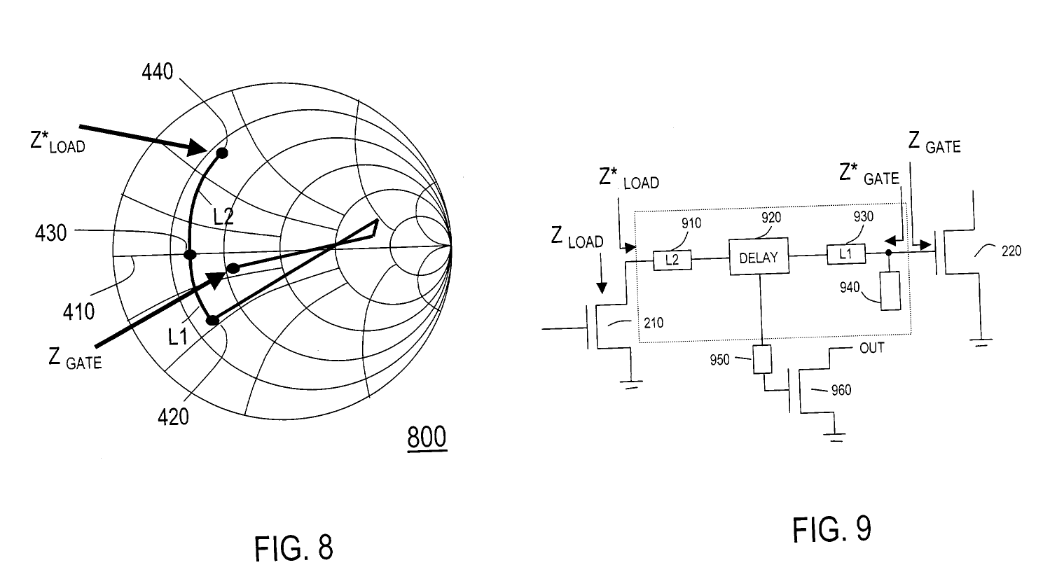

FIGS. 8 and 9 depict another Smith chart 800. In this embodiment amplifiers 210 and 220 and the network that includes transmission lines 910 and 930 having lengths L2 and L1 may be separated by a delay segment 920. Again, the passive network may be more complex than a single piece of transmission line. Note the addition of single-ended transmission line 940 to the gate of transistor 220. It should be pointed out again that simultaneous matching of input and output in the core amplifiers will lead to transmission line segments which cross the horizontal axis 410 of Smith chart 800. A lossless delay line 920 has been added at this point, and further, a transmission line 950 and transistor 960 have been added to provide a tap point inserted into delay 920.

Because of the use of distributed elements in the oscillator design, oscillator signals with desirable phase differences can be tapped out of the oscillator. The use of microstrip on the die for the passive low-loss network of the oscillator allows for seamless generation of multi-phase oscillator signals correct-by-construction. True and complement signals having 180 degree phase separation may be provided through tap points on the appropriate amplifier circuits. Other embodiments with additional tap points to provide 90 degree phase separation may provide sine, cosine, negative sine and negative cosine signals. The delay elements may be designed to provide quadrature signals or other phase shifted signals. Printed transmission lines are broadband in frequency and adaptable to Integrated Circuit (IC) fabrication technologies at RF and microwave frequencies. By choosing the length L of the microstrip line and appropriately segmenting the impedance conversion transmission line, a delay element of arbitrary delay may be inserted between segments of the transmission line to provide the desired phase delay. Embodiments of the present invention for oscillator 30 have shown to operate at frequencies higher than 64 GHz, even in the 100 GHz range and above.

Embodiments of RF amplifier circuits having microstrip segments and delay elements may provide oscillations at frequencies as high as 0.9fₘₐₓ, although this is not a limitation of the present invention. The distributed-element realization of the network connecting the transistors provides a multi-phase oscillator design, with virtually any phase relation provided by tapping out signals at proper points along the distributed passive network. By opening the oscillator loop and deleting the delay segments, Low Noise Amplifiers (LNAs) may be constructed.

By now it should be understood that an oscillator operating close to transistor's fₘₐₓ has been described. By designing several repetitions of an amplifier using simultaneous input and output matching, the oscillator may provide optimum pumping for a given transistor technology. Even though the phase condition for oscillation is not guaranteed by matching the input impedance to the output impedance, the described technique provides for the insertion of real characteristic impedance delays at strategic points. By inserting these delays at points where the impedance transformer network crosses the real axis of the Smith chart, the phase condition for oscillation is met.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

What is claimed is:

1. A circuit comprising:
a delay element on microstrip that provides phase shift to an oscillator without affecting a gain of the oscillator.

2. The circuit of claim 1 wherein the oscillator further includes a plurality of serially connected RF amplifiers where first and second microstrip segments connect a drain of one RF amplifier to a gate of another RF amplifier with the delay element formed between the first and second microstrip segments.

3. The circuit of claim 2 wherein the delay element has substantially real characteristic impedance.

4. The circuit of claim 3 where the amplifiers in the oscillator are simultaneously input and output impedance matched.

5. The circuit of claim 3 further including tap points in the plurality of serially connected RF amplifiers to provide quadrature signals.

6. The circuit of claim 2 wherein the first and second microstrip segments form a single impedance conversion transmission line used to convert an impedance at the drain of a one of the RF amplifiers to conjugate match an impedance at the gate of a next RF amplifier in the plurality of serially connected RF amplifiers.

7. A circuit comprising:
a plurality of amplifier circuits with a drain of an amplifier circuit coupled by microstrip segments to a gate of another amplifier circuit with a real characteristic impedance delay element between the microstrip segments, where the microstrip segments and the real characteristic impedance delay elements serially connect the amplifier circuits to provide oscillation.

8. The circuit of claim 7 wherein tap points distributed along a passive network provide multi-phase signals generated by the oscillator circuit.

9. The circuit of claim 7 wherein the real characteristic impedance delay elements on microstrip provide phase shift and the microstrip segments cause an impedance at the drain of the amplifier circuit to conjugate match an impedance at a gate of the another amplifier circuit to provide a gain.

10. The circuit of claim 7 wherein the real characteristic impedance delay elements on microstrip provide phase shift and the microstrip segments cause an impedance at the gate of the amplifier circuit to conjugate match an impedance at a drain of the another amplifier circuit to provide a gain.

11. The circuit of claim 7 wherein the real characteristic impedance delay element is on the microstrip between segments.

12. The circuit of claim 7 wherein the real characteristic impedance delay element provides phase delay without affecting a gain of the amplifier circuit.

13. The circuit of claim 7 wherein a loop is closed on the serially connected amplifier circuits at a point where a sum of delays through delay elements and amplifier circuits provide a phase delay of 360 degrees or an integer multiple thereof.

14. A system comprising:
a Static Random Access Memory (SRAM); and
a communication processor coupled via an external bus to the SRAM, where the communication processor receives a modulated signal, where the communication processor includes,
an oscillator circuit having a series of RF amplifier circuits each having a drain coupled by microstrip segments to a gate of a next RF amplifier circuit with a delay element between the microstrip segments, where the microstrip segments and the delay elements connecting the series of RF amplifier circuits provide oscillation near an Fmax of the RF amplifier circuits, and
a mixer coupled to receive the modulated signal and a signal from the oscillator circuit to frequency down convert the modulated signal.

15. The system of claim 14, wherein a feedback signal in the series of RF amplifier circuits closes a loop for the oscillator circuit and tap points from the delay elements provide a sine, a cosine, a negative sine and a negative cosine signal.

16. The system of claim 14, wherein the microstrip segments form a single impedance conversion transmission line used to convert an impedance at the gate of one RF amplifier to match an impedance at the drain of another RF amplifier.

17. A method comprising:
demodulating a received wireless signal using an oscillator signal generated by a plurality of Radio Frequency (RF) amplifiers in series with a drain of one RF amplifier circuit coupled by microstrip segments to a gate of another RF amplifier circuit in the series, where the microstrip segments determine a gain of the RF amplifiers and real characteristic impedance delay elements between the microstrip segments determine a phase delay in generating the oscillation signal near an Fmax of the RF amplifiers.

18. The method of claim 17, further comprising:
closing a loop on the plurality of RF amplifiers based on constructive feedback of a signal phase delayed by the resistive delay elements regardless of whether the plurality of RF amplifiers is an odd number or even number.

19. The method of claim 17, further comprising:
constructing a delay element on microstrip that provides the phase delay to the oscillator signal without affecting the gain of the RF amplifiers.

20. The method of claim 17, wherein closing a loop on the plurality of RF amplifiers further comprises:
selecting a point on the serially connected RF amplifier circuits where a sum of delays for the real characteristic impedance delay elements and RF amplifier circuit delays provide a phase delay of 360 degrees or integer multiple thereof.
